(19) United States
(12) Patent Application Publication
(10) Pub. No.: US 2024/0315054 A1
(43) Pub. Date: Sep. 19, 2024

(54) Upside-Down DRAM Package Structure

(71) Applicant: Apple Inc., Cupertino, CA (US)

(72) Inventors: Jiongxin Lu, Cupertino, CA (US); Kunzhong Hu, Cupertino, CA (US)

(21) Appl. No.: 18/184,527

(22) Filed: Mar. 15, 2023

(51) Int. Cl. H10B 80/00; H01L 23/00; H01L 25/065

(52) U.S. Cl. CPC H10B 80/00; H01L 24/16; H01L 24/48; H01L 25/0657; H01L 21/561; H01L 24/32; H01L 24/33; H01L 24/73; H01L 24/92; H01L 2224/16225; H01L 2224/32145; H01L 2224/32225; H01L 2224/33181; H01L 2224/48091; H01L 2224/48225; H01L 2224/73203; H01L 2224/73215; H01L 2224/73265; H01L 2224/92247; H01L 2924/1436

(57) ABSTRACT

Electronic package and package on package (PoP) structures are described. The electronic package may be a top electronic package in a PoP structure. In an embodiment, the top electronic package includes back-to-face stacked dies and the top electronic package is inverted such that the stacked dies are between the top package substrate and an underlying package in a PoP structure. In an embodiment, the top electronic package includes face-to-back stacked dies such that the top die of the top electronic package is facing the underlying package in a PoP structure.

### BACKGROUND

### Field

Embodiments described herein relate to semiconductor packaging. More particularly, embodiments relate to package arrangements for stress mitigation.

### Background Information

The current market demand for portable and mobile electronic devices such as mobile phones, personal digital assistants (PDAs), digital cameras, portable players, gaming, and other mobile devices requires the integration of more performance and features into increasingly smaller spaces. As a result, various multiple-die packaging solutions such as system in package (SiP) and package on package (PoP) have become more popular to meet the demand for higher die/component density devices. In one implementation, memory dies or packages such as dynamic random-access memory (DRAM), which is generally considered a volatile memory, and/or non-volatile memory die or package, such as flash (e.g. NAND), are stacked on top of a logic die or package (e.g., application-specific integrated circuit (ASIC)) or system on chip (SoC). As the market for portable and mobile electronic devices advances larger memory capability is required of the memory die or package. In one implementation, multiple memory dies are stacked vertically to increase the memory in a top memory die package.

### SUMMARY

Electronic package and package on package (PoP) structures are described. In an embodiment, an electronic package includes a package substrate including a front side and a back side, a first die including a face side and a back side, the back side attached to the front side of the package substrate, and a first wire bond connecting the face side of the first die to the front side of the package substrate. A molding layer may encapsulate the first die and the wire bond on the package substrate. Additional dies may be stacked on the first die and also encapsulated within the molding layer.

In an embodiment, a back side of a second die stacked on the first die faces the face side of the first die. For example, a second wire bond can connect the face side of the second die to the front side of the package substrate. In such an embodiment, a plurality of vertical interconnects extends through a thickness of the molding layer and in contact with the front side of the package substrate. In this manner, when the electronic package is a top electronic package of a PoP structure (or even when the electronic package is a standalone package) the build-up structures of the first and second dies face the underlying first package in the PoP structure, and can be protected against external stresses by the package substrate of the top package.

In an embodiment, a face side of a second die stacked on the first die faces the face side of the first die. In such an embodiment, a plurality of conductive pillars extend from the face side of the second die toward the front side of the package substrate. In this manner, when the electronic package is a top electronic package of the PoP structure, the build-up structure of the second die can be protected against external stresses by the semiconductor substrate of the second die.

### BRIEF DESCRIPTION OF THE DRAWINGS

FIG. 1A is a schematic cross-sectional side view illustration of a PoP structure including cracks in a die of the top electronic package.

FIG. 1B is a schematic cross-sectional side view illustration of cracks formed within the build-up structure of a die.

FIG. 2 is a schematic cross-sectional side view illustration of a PoP structure with inverted top electronic package in accordance with an embodiment.

FIG. 3 is a schematic cross-sectional side view illustration of a PoP structure in which the top electronic package includes face-to-face stacked dies in accordance with an embodiment.

FIG. 4 is a flow chart illustrating a process of forming a PoP structure in accordance with an embodiment.

FIGS. 5A-5D are schematic cross-sectional side view illustrations for a process of forming a PoP structure in accordance with an embodiment.

FIG. 6 is a flow chart illustrating a process of forming an inverted top electronic package in accordance with an embodiment.

FIGS. 7A-7D are schematic cross-sectional side view illustrations for a process of forming an inverted top electronic package in accordance with an embodiment.

FIG. 8 is a flow chart illustrating a process of forming an electronic package with face-to-face stacked dies in accordance with an embodiment.

FIGS. 9A-9C are schematic cross-sectional side view illustrations for a process of forming an electronic package with face-to-face stacked dies in accordance with an embodiment.

### DETAILED DESCRIPTION

Embodiments describe electronic package and package on package (PoP) structures in which a face side of a top die is oriented away from the topmost surface of the package, which may be the top package in a PoP structure. In an embodiment, a top electronic package includes a package substrate including a front side and a back side and a first die (such as a DRAM die) including a face side and a back side. In an embodiment, the back side of the first die is attached to the front side of the package substrate, and a first wire bond connects the face side of the first die to the front side of the package substrate. Additional dies can be stacked on the first die. Additional dies are optional. A molding layer can further encapsulate the first die (and any additional stacked dies) and the wire bond(s) on the package substrate. In an embodiment a plurality of vertical interconnects extend through a thickness of the molding layer and be in contact with the front side of the package substrate. The plurality of vertical interconnects can provide electrical connection to the underlying package. In such an arrangement, the top package can be inverted, such that the package substrate is located furthest away from the underlying package. In another embodiment, a second die is attached to the first die with a face side of the second die attached to the face side of the first die, and a plurality of conductive pillars extend from the face side of the second die toward the face side of the package substrate.

Traditional dynamic random access memory (DRAM) packages commonly include multiple stacked DRAM dies which are each wire bonded to a package substrate. As the demand for larger memory capability and smaller packages continues the DRAM dies are continually thinner, and the dielectric layers used to form the build-up structures in DRAM dies can become less robust with the selection of low-k materials. Furthermore, it has been observed that particle contamination can be introduced during testing of the die stack after overmolding. This combination of thinner dies, less robust materials in the build-up structures, and contamination can potentially lead to crack formation in the top DRAM die when subjected to external stress. In accordance with embodiments the top DRAM die may be protected from external stress by orienting the face side of the top DRAM die away from the topmost surface of the package which may be exposed during downstream integration. In an embodiment the top DRAM die may be protected from external stress in an inverted package arrangement in which the package substrate is exposed and can protect underlying DRAM dies. In another embodiment, a top DRAM die is stacked face down onto an underlying DRAM die that is facing the top DRAM die. In this manner, the back side of the top DRAM die semiconductor substrate can protect the susceptible build-up structures from stress. It is to be appreciated that while embodiments are described with particular regard to PoP arrangements with stacked DRAM dies that embodiments are not so limited and may be applicable to other die types.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer “between” layers may be directly in contact with the layers or may have one or more intervening layers.

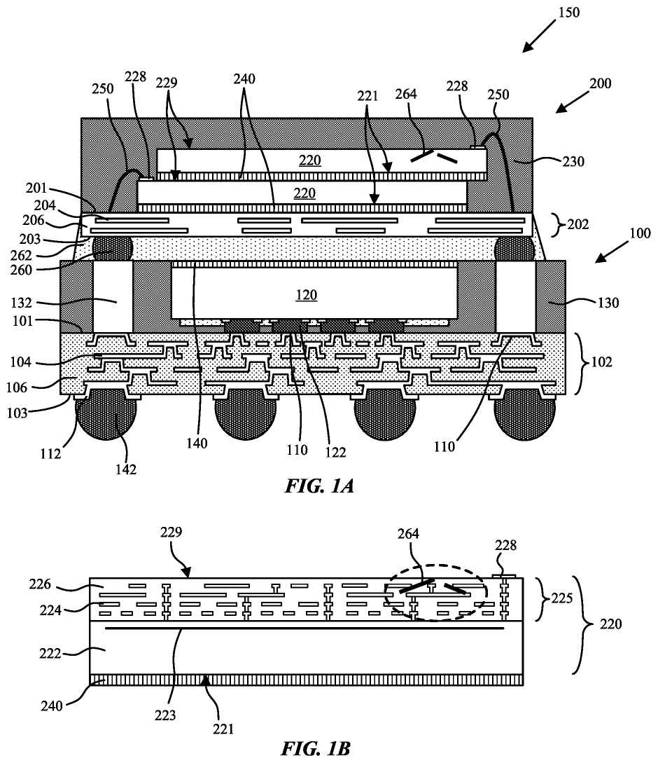

Referring now to FIG. 1A, a cross-sectional side view illustration is provided of a PoP structure including cracks in the top electronic package. The bottom package 100 may include a first package substrate 102, which may be a redistribution layer (RDL), a first die 120 attached to a top side 101 of the first package substrate 102, and molding layer 130 encapsulating the first die 120 on the top side 101 of the first package substrate 102. A first plurality of vertical interconnects 132, such as metal (e.g. copper) pillars, through mold vias, or printed circuit board (PCB) bars, extend from the top side 101 of the first package substrate 102 and through a thickness of the molding layer 130. The vertical interconnects 132 may protrude from contact pads 110 in the first package substrate 102. A back side 103 of the first package substrate 102 may additionally include a plurality of underbump metallurgy (UBM) pads 112, and solder bumps 142 attached thereto. The first package substrate may include one or more metallization layers 104 and dielectric layers 106. The first package substrate 102 can be a variety of substrates, including cored and coreless substrate. In an embodiment, the first package substrate 102 is an RDL formed directly on and in electrical contact with the terminals 122 of the first die 120 and the vertical interconnects 132. Alternatively, the first package substrate 102 is pre-formed, with the first die 120 being mounted onto the first package substrate 102 with solder bumps. A variety of configurations are possible.

As shown, a top electronic package 200 is mounted on the bottom electronic package 100 with a plurality of solder bumps 260 and underfilled with underfill material 262. In the exemplary illustration the top electronic package includes a package substrate 202 including one or more metallization layers 204 and dielectric layers 206, and one or more dies 220 mounted onto the package substrate 202. As shown, the dies 220 may be mounted face side 229 up, with back sides 221 attached with an adhesive layer 240. The face sides 229 in turn can be connected to the package substrate 202 with wire bonds 250, which can be bonded to contact pads 228 on the face sides 229 of the dies 220. The one or more stacked dies 220 and wire bonds 250 can be encapsulated within a molding layer 230 on a front side 201 of the package substrate 202. As shown in FIG. 1A, it has been observed that the topmost die 220 may be susceptible to external stress, and the formation of cracks 264.

FIG. 1B is a schematic cross-sectional side view illustration of cracks formed within the build-up structure of a die 220. The die 220 can be a variety of dies including logic, or memory such as DRAM or NOT-AND (NAND), etc. In an embodiment the die 220 is a DRAM die including a plurality of devices 223 (e.g. transistors) formed in a semiconductor substrate 202 along with capacitors formed in the build-up structure 225 and/or semiconductor substrate 222. The build-up structure 225 may include a plurality of metallization layers 224 and dielectric layers 226 formed using a suitable technique such as damascene processing, and a plurality of contact pads 228 on the face side 229 of the die 220. An adhesive layer 240 may be applied to the back side 221 of the die for attaching to a package substrate 202 or another underlying die 220. The dielectric layers 226 can be formed of suitable materials including silicon dioxide (SiO₂), as well as low-k materials such as fluorinated silicate glass (FSG), organosilicate glass (OSG), porous OSG (P-OSG) film, etc. with a dielectric constant value (k) less than 4.0. Such low-k materials may be particularly susceptible to crack 264 formation.

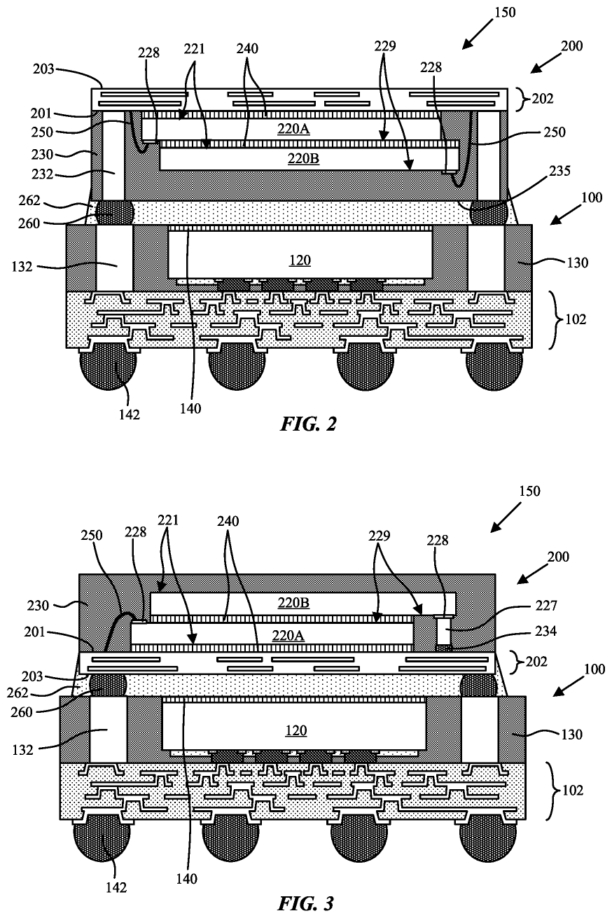

FIG. 2 is a schematic cross-sectional side view illustration of a PoP structure with inverted top electronic package in accordance with an embodiment. As shown, the PoP structure 150 includes a first electronic package 100 and a second electronic package 200 mounted on the first electronic package 100. The second electronic package 200 includes a package substrate 202 including a front side 201 and a back side 203, where the front side 201 of the package substrate 202 faces the first electronic package 100. The back side 221 of a first die 220A is attached to the front side 201 of the package substrate, a first wire bond 250 connects the face side 229 of the first die 220A to the front side 201 of the package substrate, and a molding layer 130 encapsulates the first die 220A and the wire bond 250 on the package substrate. One or more additional dies 220 (e.g. second die 220B and any intervening dies) may then be stacked onto one another in a similar fashion, and optionally with a staggered (or stepped) relationship as shown to accommodate the landing pads 228 and wire bonds 250. Each of the one more additional dies may be attached with a back side 221 on the face side 229 of the immediately underlying die 220. The stacked dies 220 (e.g. 220A, 220B) may be the same or different types of dies. There may be multiple dies 220 in the same layer. In an embodiment the stacked dies are memory dies, such as DRAM dies.

As shown in FIG. 2 a plurality of vertical interconnects 232 can extend through a thickness of the molding layer 230 to electrically connect the package substrate 202 and dies 220 to the first package 100. For example, the plurality of vertical interconnects 232 can be bonded to the first electronic package 100 with a plurality of package solder bumps 260. For example, a planarized surface 235 can span, and be formed of, the vertical interconnects 232 and the molding layer 230. The package solder bumps 260, or ball grid arrays (BGAs), can be placed on the vertical interconnects of the planarized surface 235. While not illustrated, intermediate routing layers can also be included, for example on the planarized surface 235 for additional routing.

In the particular embodiment illustrated in FIG. 2 the back side 203 of the package substrate 202 is not overmolded. This may facilitate a reduced total thickness of the structure. In the inverted arrangement the package substrate 202 can function as a physical barrier to the dies 220 and protect against mechanical stress. Additionally, the face sides 229 of the dies 220 that are susceptible to contamination (e.g. second dies 220B) are facing toward the first package 100, and the space between the first package 100 and second package 200 can be filled with an underfill material 262.

Referring now to FIG. 3, a schematic cross-sectional side view illustration is provided of a PoP structure 150 in which the second electronic package 200 includes face-to-face stacked dies 220 in accordance with an embodiment. The second electronic package 200 in such an embodiment may include a plurality of stacked dies 220 with the topmost die (e.g. second die 220B) facing the package substrate 202. As shown, a first die 220A is attached back side 221 to the package substrate 202 with an adhesive layer 240. As shown, the second die 220B includes a face side 229 that faces the face side 229 of the first die 220A. In a two die arrangement, the face side 229 of the second die can be attached to the face side 229 of the first die 220A with an adhesive layer 240. Where there are more than two stacked dies, the second die 220B may be a top die that is stacked over a plurality of underlying dies (e.g. 220A . . . n). As shown, a plurality of conductive pillars 227 extend from the face side 229 of the second die 220B toward the front side 201 of the package substrate 202 in order to provide electrical connection. For example, the plurality of conductive pillars 227 can be bonded to the package substrate 202 with a plurality of solder bumps 234. Similar to other arrangements, the stacked dies 220 (e.g. 220A, 220B) may be the same or different types of dies. In an embodiment the stacked dies are memory dies, such as DRAM dies.

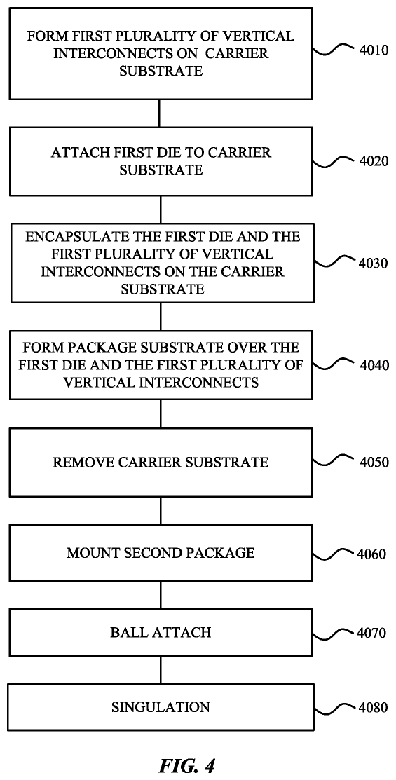

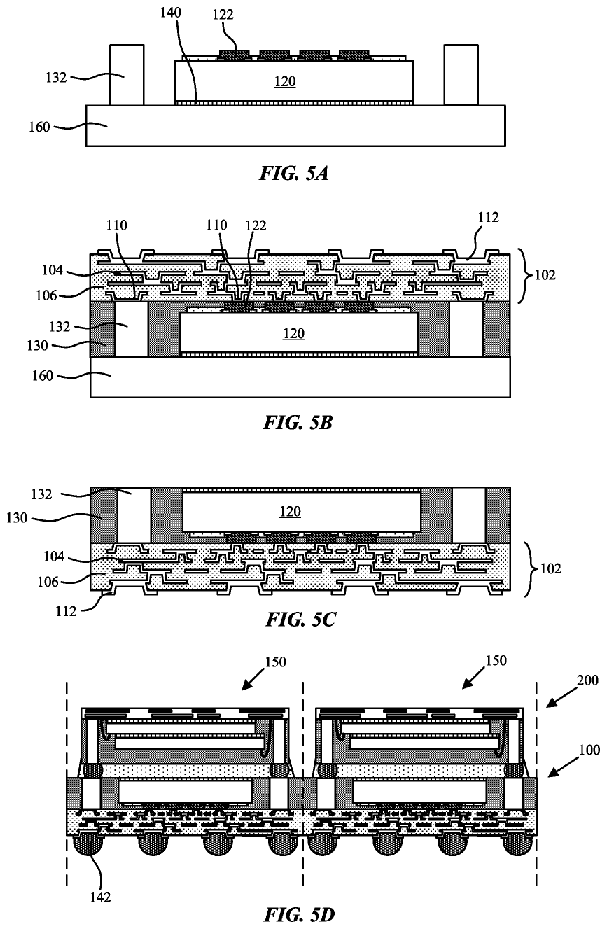

Referring now to FIG. 4 and FIGS. 5A-5D, FIG. 4 is a flow chart illustrating a process of forming a PoP structure in accordance with an embodiment; FIGS. 5A-5D are schematic cross-sectional side view illustrations for a process of forming a PoP structure in accordance with an embodiment. In interest of clarity and conciseness the process flow of FIG. 4 is discussed concurrently with FIGS. 5A-5D. As shown in FIG. 5A, at operation 4010 a first plurality of vertical interconnects 132 is optionally formed on a carrier substrate 160. The carrier substrate 160 may be a suitable substrate such as a semiconductor wafer, glass, metal plate, etc. The vertical interconnects 132 may be conductive pillars formed by a plating technique, or alternatively be placed components such as PCB bars. At operation 4020 a die 120 is then attached to the carrier substrate 160 with an adhesive layer 140, the die 120 face side up with terminals 122 facing away from the carrier substrate 160. As shown in FIG. 5B, the first die 120 and the first plurality of vertical interconnects 132 are encapsulated on the carrier substrate 160 at operation 4030. For example, encapsulation may be accomplished with a molding layer, or other suitable insulator gap fill material such as oxide, nitride, etc. This may be followed by a planarization operation to expose terminals 122 and vertical interconnects 132. As an alternative fabrication sequence, the vertical interconnects 132 can optionally be formed after encapsulation using and etch and fill technique such as through mold via (TMVs) or through insulator vias (TIVs). This may be followed by formation of a package substrate 102 over the first die 120 and the first plurality of vertical interconnects 132 at operation 4040. The package substrate 102 may be a redistribution layer (RDL) formed using thin film processing technique to form one or more metallization layers 106 and dielectric layers 106, including landing pads 110 on the vertical interconnects 132 and terminals 122, and terminating in UBM pads 112. The carrier substrate 160 may then be removed at operation 4050.

Second (top) packages 200 may then be mounted over the reconstituted substrate including the first dies 120 at operation 4060, follow by underfill as shown in FIG. 5D. This may be followed by placement of solder bumps 142 onto the UBM pads 112 at operation 4070, followed by singulation of multiple PoP structures 150 at operation 4080. The second packages 200 may be packages such as those illustrated and described with regard to FIGS. 2-3.

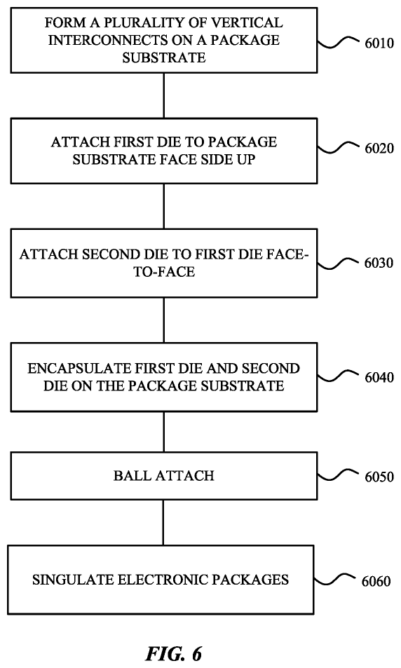

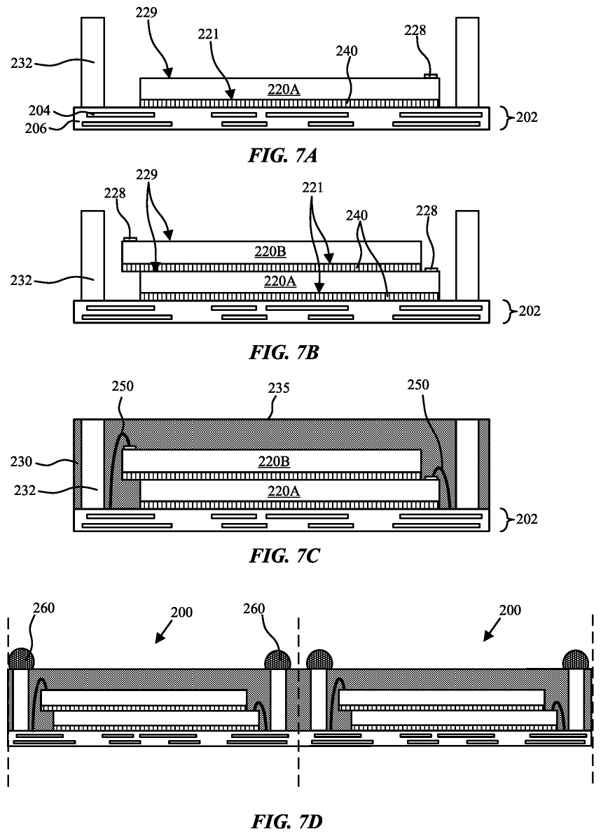

Referring now to FIG. 6 and FIGS. 7A-7D, FIG. 6 is a flow chart illustrating a process of forming an inverted top electronic package in accordance with an embodiment. FIGS. 7A-7D are schematic cross-sectional side view illustrations for a process of forming an inverted top electronic package in accordance with an embodiment. In interest of clarity and conciseness the process flow of FIG. 6 is discussed concurrently with FIGS. 7A-7D. As shown in FIG. 7A, a plurality of vertical interconnects 232 may be pre-formed on the package substrate 202 at operation 6010, for example by plating technique. Alternatively, the vertical interconnects 232, such as PCB bars, can be mounted onto the package substrate 202, or can be electrolytic plated. Package substrate 202 may be any suitable substrate including cored or coreless substrates, glass-reinforced epoxy laminates, polymer laminates, etc. At operation 6020 a first die 220A is attached to package substrate 202. This can be face side 229 up with the back side 221 attached to the package substrate 202 with an adhesive layer. A second die 220B is then attached face up over the first die 220A at operation 6030. This may be repeated for stacks of multiple dies, with the topmost die face side 229 up. Wirebonds 25 can then be provided to connect the dies (e.g. 220A, 220B) to the package substrate 202, followed by encapsulation with a molding layer 230 at operation 6040, and as shown in FIG. 7C. (In an alternate process flow film on wire (FOW) can be utilized including attaching a first die 220A, then wirebonding the first die, then FOW, then attaching a second die 220B, and wirebonding the second die.

This may be followed by a planarization operation form a planarized surface 235 and expose the vertical interconnects 232. Additional routing can then optionally be provided if desired. This can be followed by placement of solder bumps 260 onto the vertical interconnects 232 or optional routing at operation 6050, followed by singulation of multiple packages 200 at operation 6060, as shown in FIG. 7D.

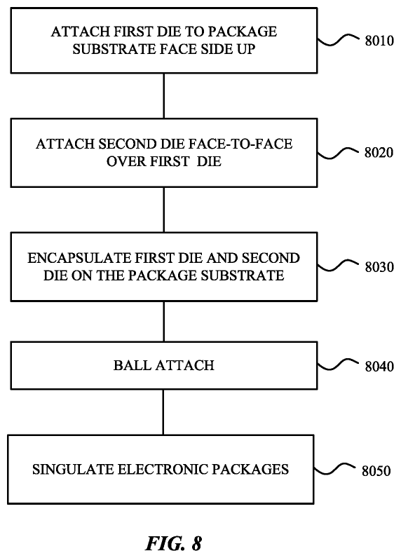

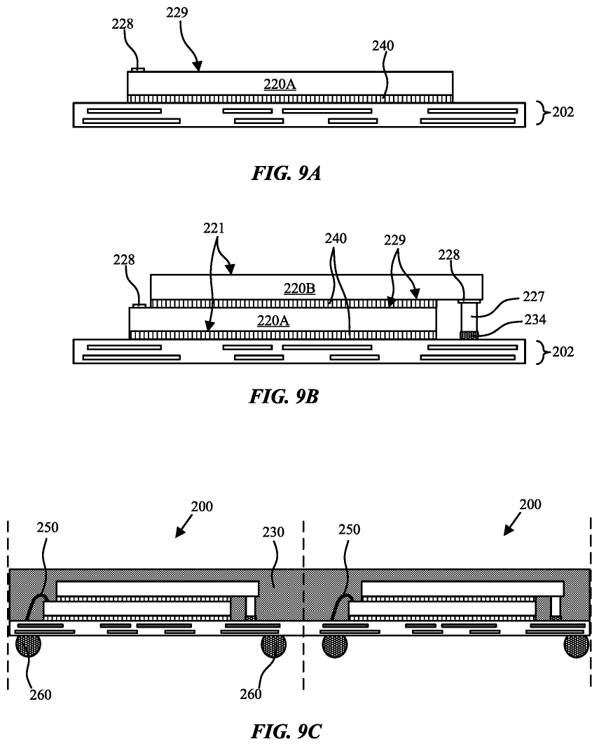

Referring now to FIG. 8 and FIGS. 9A-9C, FIG. 8 is a flow chart illustrating a process of forming an electronic package with face-to-face stacked dies in accordance with an embodiment; FIGS. 9A-9C are schematic cross-sectional side view illustrations for a process of forming an electronic package with face-to-face stacked dies in accordance with an embodiment. In interest of clarity and conciseness the process flow of FIG. 8 is discussed concurrently with FIGS. 9A-9C. As shown in FIG. 9A, at operation 8010 a first die 220A is attached to package substrate 202. This can be face side 229 up with the back side 221 attached to the package substrate 202 with an adhesive layer. As shown in FIG. 9B, at operation 8020 a second die 220B is attached face-to-face over the first die 220A. The second die 220B may be attached to the first die 220A, or an intervening die in a die stack, with an adhesive layer 240. The second die 220B may be a topmost die in the die stack. As shown, the face side 229 of the second die 220B is facing the face side 229 of the first die 220A. The second die 220B may additionally include a plurality of conductive pillars 227 extending from the face side 229 of the second die 220B toward the front side 201 of the package substrate 202 in order to provide electrical connection. For example, the plurality of conductive pillars 227 can be bonded to the package substrate 202 with a plurality of solder bumps 234.

As shown in FIG. 9C, the first and second dies 220 (e.g. 220A, 220B) can then be encapsulated on the package substrate 202 with a molding layer 230 at operation 8030. This can be followed by placement of solder bumps onto the opposite side of the package substrate 202 at operation 8040, followed by singulation of multiple packages 200 at operation 8050.

In utilizing the various aspects of the embodiments, it would become apparent to one skilled in the art that combinations or variations of the above embodiments are possible for forming a PoP structure in which the topmost die is facing away from the topmost surface of the top package in the PoP structure. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An electronic package comprising:
a package substrate including a front side and a back side;
a first die including a face side and a back side, the back side attached to the front side of the package substrate;
a first wire bond connecting the face side of the first die to the front side of the package substrate; and
a molding layer that encapsulates the first die and the wire bond on the package substrate.

2. The electronic package of claim 1, further comprising a plurality of vertical interconnects extending through a thickness of the molding layer and in contact with the front side of the package substrate.

3. The electronic package of claim 2, wherein the back side of the package substrate is not overmolded.

4. The electronic package of claim 3, further comprising:
a planarized bottom surface spanning the plurality of vertical interconnects and the molding layer; and
a plurality of solder bumps on the plurality of vertical interconnects.

5. The electronic package of claim 2, further comprising:
a second die that includes a face side and a back side, the back side of the second die facing the face side of the first die; and
a second wire bond connecting the face side of the second die to the front side of the package substrate.

6. The electronic package of claim 5, wherein the first die is a first memory die.

7. The electronic package of claim 6, wherein the second die is a second memory die, and the second memory die includes a build-up structure including a low-k dielectric layer.

8. The electronic package of claim 1, further comprising:
a second die including a face side and a back side, the face side of the second die facing the face side of the first die; and
a plurality of conductive pillars extending from the face side of the second die toward the front side of the package substrate.

9. The electronic package of claim 8, wherein the plurality of conductive pillars is bonded to the package substrate with a plurality of solder bumps.

10. The electronic package of claim 8, wherein the first die is a first memory die.

11. The electronic package of claim 10, wherein the second die is a second memory die, and the second memory die includes a build-up structure including a low-k dielectric layer.

12. A package on package structure comprising:
a first electronic package;
a second electronic package mounted on the first electronic package, the second electronic package comprising:
a package substrate including a front side and a back side, wherein the front side of the package substrate faces the first electronic package;
a first die including a face side and a back side, the back side attached to the front side of the package substrate;
a first wire bond connecting the face side of the first die to the front side of the package substrate; and
a molding layer that that encapsulates the first die and the wire bond on the package substrate.

13. The package on package structure of claim 12, further comprising a plurality of vertical interconnects extending through a thickness of the molding layer and in contact with the front side of the package substrate.

14. The package on package structure of claim 13, wherein the plurality of vertical interconnects is bonded to the first electronic package with a plurality of package solder bumps.

15. The package on package structure of claim 13, wherein the back side of the package substrate is not overmolded.

16. The package on package structure of claim 13, further comprising:
a second die that includes a face side and a back side, the back side of the second die facing the face side of the first die; and
a second wire bond connecting the face side of the second die to the front side of the package substrate.

17. The package on package structure of claim 16, wherein the first die is a first memory die, and the second die is a second memory die, and the second memory die includes a build-up structure including a low-k dielectric layer.

18. The package on package structure of claim 12, further comprising:
a second die including a face side and a back side, the face side of the second die facing the face side of the first die; and
a plurality of conductive pillars extending from the face side of the second die toward the front side of the package substrate.

19. The package on package structure of claim 18, wherein the first die is a first memory die, and the second die is a second memory die, and the second memory die includes a build-up structure including a low-k dielectric layer.

20. The package on package structure of claim 18, wherein the plurality of conductive pillars is bonded to the package substrate with a plurality of solder bumps.
